(19) United States
(12) Patent Application Publication
(10) Pub. No.: US 2025/0370367 A1
(43) Pub. Date: Dec. 4, 2025

(54) LIGHT EMITTING ELEMENT PANEL, PRINT HEAD, IMAGE FORMING APPARATUS. AND LIGHT EMITTING ELEMENT PANEL MANUFACTURING METHOD

(71) Applicant: SHARP KABUSHIKI KAISHA, Sakai City (JP)

(72) Inventors: Atsushi Ueda, Sakai City (JP); Songhuan Piao, Sakai City (JP); Akito Teramoto, Sakai City (JP); Hiroshi Yamamoto, Sakai City (JP); Kenzo Ohkubo, Sakai City (JP)

(21) Appl. No.: 19/191,596

(22) Filed: Apr. 28, 2025

(30) Foreign Application Priority Data
May 29, 2024 (JP) 2024-087039

(51) Int. Cl. G03G 15/04; H10K 59/80; H10K 59/95

(52) U.S. Cl. CPC G03G 15/04054; H10K 59/95; G03G 15/0409; H10K 59/879

(57) ABSTRACT

A film-like light emitting element panel includes a plurality of light emitting elements arrayed in a line. Positioning portions for positioning the plurality of light emitting elements at a reference positioning position on a positioning target object are provided on both end portions of the light emitting element panel in an array direction along the linear direction of the plurality of light emitting elements, and a virtual straight line connecting centers of the pair of positioning portions respectively provided on the both end portions lies within a width of the plurality of light emitting elements in a width direction orthogonal to the array direction.

### BACKGROUND OF THE INVENTION

### Field of the Invention

The present disclosure relates to a light emitting element panel capable for use in an image forming apparatus such as a copying machine, a multifunction machine, a printer, and a facsimile machine, a print head, an image forming apparatus, and a light emitting element panel manufacturing method.

### Description of the Background Art

A conventional technique describes a print head provided with a rigid light emitting element substrate including a plurality of light emitting elements arrayed in a line.

Specifically, in the print head (LED array print head) described in the conventional technique, positioning portions (pin holes) for positioning the plurality of light emitting elements (LED chip array) at a reference positioning position on a positioning target object (heat sink) are provided on both end portions of the light emitting element substrate in an array direction along the linear direction of the plurality of light emitting elements. This enables to accurately position the plurality of light emitting elements (LED chip array) at the reference positioning position on the positioning target object (heat sink).

However, in a case where a film-like light emitting element panel is used in place of a rigid light emitting element substrate, the following inconvenience occurs.

That is, conventionally, in a case where a light emitting element panel is positioned at a reference positioning position on a positioning target object (for example, a support member that supports a light emitting element panel), the light emitting element panel is positioned at the reference positioning position on the positioning target object by aligning a contour line of the light emitting element panel with the reference positioning position provided on the positioning target object (for example, by bringing the contour line into contact with a reference wall or a reference mark).

However, in positioning as described above, positioning accuracy between the panel outer shape and the plurality of light emitting elements is not good due to a dimensional variation in the panel outer shape of the light emitting element panel, or the like. Therefore, the light emitting element panel is likely to deviate from the reference positioning position on the positioning target object. As a result, positioning accuracy of the plurality of light emitting elements with respect to the reference positioning position on the positioning target object deteriorates. Therefore, time and effort are required in a subsequent adjustment process (for example, a position and/or an inclination of a lens array with respect to a plurality of light emitting elements, in particular, an inclination), which requires an adjustment time, and adjustment work is deteriorated.

In this regard, it is conceivable to provide a light emitting element panel with a positioning portion for positioning a plurality of light emitting elements at a reference positioning position on a positioning target object, as in the case of using a conventional rigid light emitting element substrate. However, even in a case where positioning portions are provided on a film-like light emitting element panel at random, the plurality of light emitting elements cannot be accurately positioned at a reference positioning position on a positioning target object depending on a position of the positioning portions.

In view of the above, an object of the present disclosure is to provide a light emitting element panel being a film-like light emitting element panel including a plurality of light emitting elements arrayed in a line and capable of accurately positioning the plurality of light emitting element at a reference positioning position on a positioning target object, a print head, an image forming apparatus, and a light emitting element panel manufacturing method.

### SUMMARY OF THE INVENTION

To solve the above problem, the present disclosure provides a light emitting element panel, a print head, an image forming apparatus, and a light emitting element panel manufacturing method as follows.

### (1) Light Emitting Element Panel

A light emitting element panel according to the present disclosure is a film-like light emitting element panel including a plurality of light emitting elements arrayed in a line. The light emitting element panel includes a positioning portion that positions the plurality of light emitting elements at a reference positioning position on a positioning target object, on both end portions of the light emitting element panel in an array direction along the linear direction of the plurality of light emitting elements. A virtual straight line connecting centers of a pair of positioning portions respectively provided on the both end portions lies within a width of the plurality of light emitting elements in a width direction orthogonal to the array direction.

### (2) Print Head

A print head according to the present disclosure includes a light emitting element panel according to the present disclosure, and a support member that supports the light emitting element panel. The positioning target object is the support member.

### (3) Image Forming Apparatus

An image forming apparatus according to the present disclosure includes a print head according to the present disclosure.

### (4) Light Emitting Element Panel Manufacturing Method

A light emitting element panel manufacturing method according to the present disclosure is a light emitting element panel manufacturing method of manufacturing a light emitting element panel according to the present disclosure. The light emitting element panel manufacturing method includes cutting, into each of the individual light emitting element panels, a connecting panel member in which a plurality of the light emitting element panels are connected in the width direction. The cutting includes forming the positioning portion on the light emitting element panel simultaneously with cutting into each of the light emitting element panels.

According to the present disclosure, it becomes possible to accurately position a plurality of light emitting elements at a reference positioning position on a positioning target object.

### BRIEF DESCRIPTION OF THE DRAWINGS

FIG. 1 is a cross-sectional view illustrating an image forming apparatus according to the present embodiment.

FIG. 2 is a perspective view illustrating that an example of a print head in the image forming apparatus according to the present embodiment is mounted on a main body frame, as viewed obliquely from above on a front side.

FIG. 3 is a perspective view of a state in which the print head illustrated in FIG. 2 is supported on a mounting portion, as viewed obliquely from above on the front side.

FIG. 4 is a perspective view of the print head as viewed obliquely from above on a back side.

FIG. 5 is a perspective view of the print head illustrated in FIG. 4 as viewed obliquely from below on the front side.

FIG. 6 is an exploded perspective view of the print head illustrated in FIG. 4 as viewed obliquely from above on the front side.

FIG. 7 is an exploded perspective view of the print head illustrated in FIG. 4 as viewed obliquely from below on the back side.

FIG. 8 is a cross-sectional perspective view of the print head as viewed obliquely from above on the front side.

FIG. 9 is a cross-sectional view of the print head.

FIG. 10 is a schematic diagram clearly illustrating the cross-sectional view illustrated in FIG. 9.

FIG. 11 is a plan view illustrating a state in which a flexible circuit board extends linearly on a light emitting element panel, the flexible circuit board, and a printed wiring board constituting the print head.

FIG. 12 is a perspective view for explaining an example of a first step of a manufacturing process of the print head.

FIG. 13 is a perspective view for explaining an example of a second step of the manufacturing process of the print head.

FIG. 14 is a perspective view for explaining an example of a third step of the manufacturing process of the print head.

FIG. 15 is a perspective view for explaining an example of a fourth step of the manufacturing process of the print head.

FIG. 16 is a perspective view for explaining an example of a fifth step of the manufacturing process of the print head.

FIG. 17 is a perspective view for explaining an example of a sixth step of the manufacturing process of the print head.

FIG. 18 is a plan view illustrating an example of some of a plurality of light emitting elements on a light emitting element panel, and a pair of positioning portions.

FIG. 19 is an enlarged view of enlarging the example of some of the plurality of light emitting elements on the light emitting element panel, and the pair of positioning portions illustrated in FIG. 18.

FIG. 20 is a plan view illustrating another example of some of a plurality of light emitting elements on a light emitting element panel, and a pair of positioning portions.

FIG. 21 is a schematic block diagram illustrating a cutting step and a positioning step of a manufacturing process of a light emitting element panel according to the present embodiment.

FIG. 22 is a plan view illustrating an example of a connecting panel member.

FIG. 23 is a plan view illustrating an example of a light emitting element panel cut by a conventional cutting step.

FIG. 24 is a plan view illustrating an example in which a conventional light emitting element panel is positioned with respect to a positioning target object, while using a contour line in a width direction, as a reference position.

FIG. 25 is a plan view illustrating an example of a light emitting element panel cut by a cutting step according to the present embodiment.

### DESCRIPTION OF THE PREFERRED EMBODIMENTS

Hereinafter, embodiments according to the present disclosure are described with reference to the drawings. In the following description, the same components are denoted by the same reference numerals. The names and functions of the same components are also identical. Therefore, detailed description on the same components is not repeated.

### Image Forming Apparatus

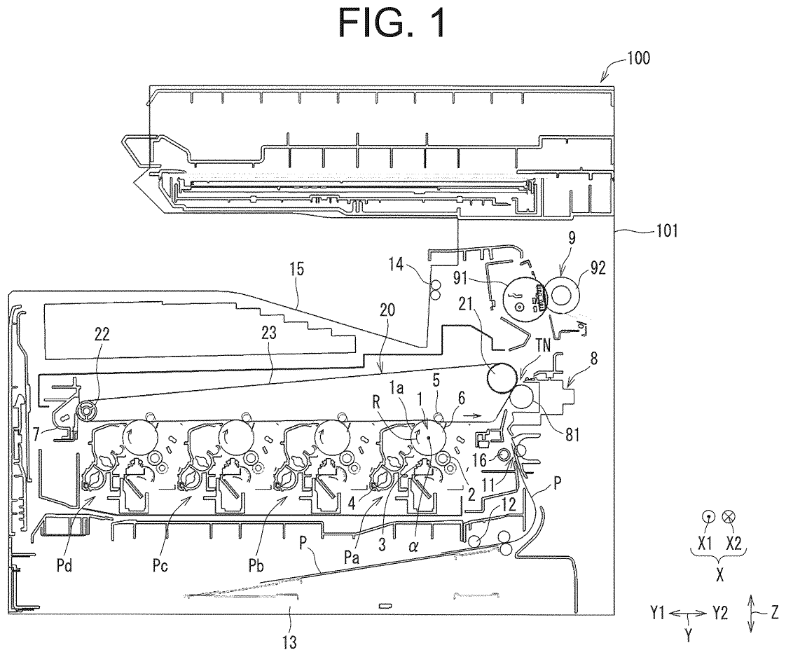

FIG. 1 is a cross-sectional view illustrating an image forming apparatus 100 according to the present embodiment. Note that, in the drawings, following description is made based on a premise that X is a rotation axis direction of a photosensitive drum 1, X1 is a front side, X2 is a back side, Y is a left-right direction orthogonal to the rotation axis direction X, Y1 is a right side, Y2 is a left side, and Z is an up-down direction orthogonal to the rotation axis direction X and the left-right direction Y.

Image data to be handled in an image forming apparatus main body 101 of the image forming apparatus 100 are associated with a color image using each color of black (K), cyan (C), magenta (M), and yellow (Y), or a monochromatic image using a single color (for example, black). Therefore, the photosensitive drum 1 (a scanned member or an image carrier), a charger 2, a print head 3, a developing device 4, a primary transfer device 5, and a drum cleaning device 6 are provided each by four to form toner images of four kinds associated with each color and four image stations Pa, Pb, Pc, and Pd are constituted each in association with black, cyan, magenta, and yellow. Note that, the image forming apparatus 100 may be a monochromatic image forming apparatus.

In each image station Pa, Pb, Pc, and Pd, the chargers 2 to 2 charge a surface 1a of the photosensitive drums 1 to 1 to be rotated and driven in a predetermined rotation direction R uniformly to a predetermined potential. The print heads 3 to 3 expose the surface 1a of the photosensitive drums 1 to 1, and form an electrostatic latent image on the surface 1a of the photosensitive drums 1 to 1. The developing device 4 develops the electrostatic latent image on the surface 1a of the photosensitive drums 1 to 1, and forms a toner image on the surface 1a of the photosensitive drums 1 to 1. Thus, a toner image of each color is formed on the surface 1a of each of the photosensitive drums 1 to 1. The drum cleaning devices 6 to 6 remove and collect residual toner on the surface 1a of the photosensitive drums 1 to 1. The primary transfer devices 5 to 5 transfer the toner image of each color on the surface 1a of the photosensitive drums 1 to 1 successively to an intermediate transfer belt 23 that circulates and moves by a drive roller 21 and a driven roller 22 of a belt drive device 20 in a superimposing manner, and form a color toner image on the intermediate transfer belt 23. A belt cleaning device 7 removes and collects the residual toner from the intermediate transfer belt 23.

A transfer nip portion TN is formed between the intermediate transfer belt 23, and a transfer roller 81 of a secondary transfer device 8. The transfer roller 81 of the secondary transfer device 8 nips a sheet P such as a recording sheet transported via a sheet transport path 11 in the transfer nip portion TN, and transfers the color toner image on the surface of the intermediate transfer belt 23 onto the sheet P, while transporting the sheet P together with the intermediate transfer belt 23. A fixing device 9 applies heat and pressure to the sheet P, while holding the sheet P between a fixing member (in this example, a fixing belt 91), and a pressing member (in this example, a pressing roller 92), and fixes the color toner image on the sheet P.

The sheet P is pulled out from a sheet feed cassette 13 by a pickup roller 12, transported through the sheet transport path 11, passes through the secondary transfer device 8 and the fixing device 9, and is discharged to a discharge tray 15 via discharge rollers 14. Registration rollers 16 and the like are disposed on the sheet transport path 11. The registration rollers 16 temporarily stop the sheet P, align a leading end of the sheet P, and thereafter, start transport of the sheet P as timed with transfer timing of a toner image at the transfer nip portion TN between the intermediate transfer belt 23 and the transfer roller 81.

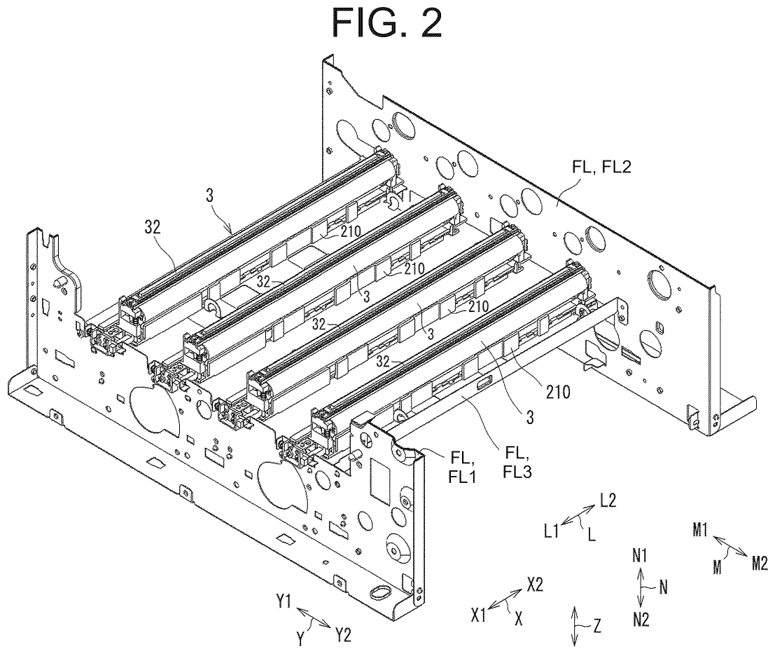

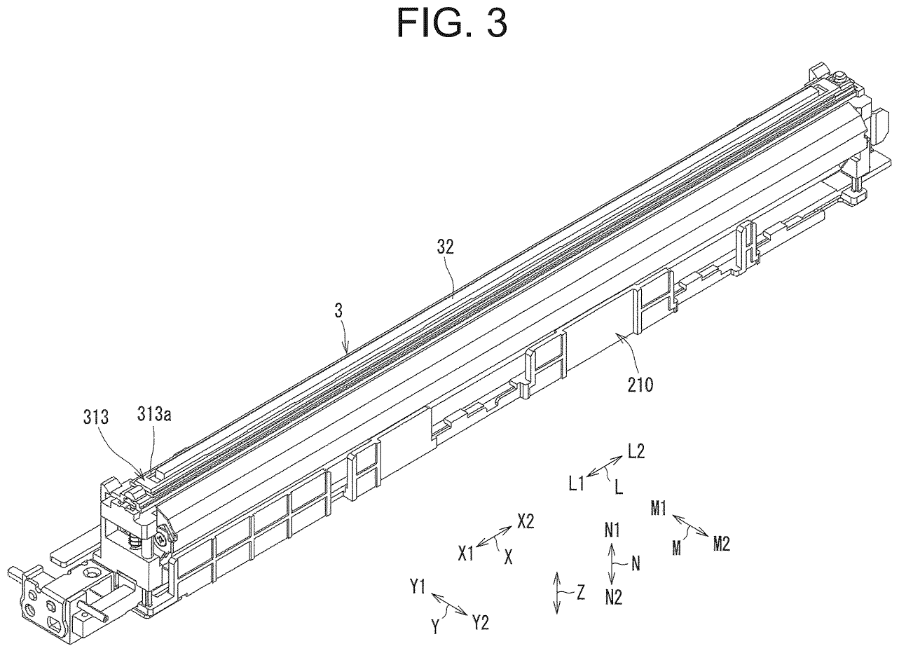

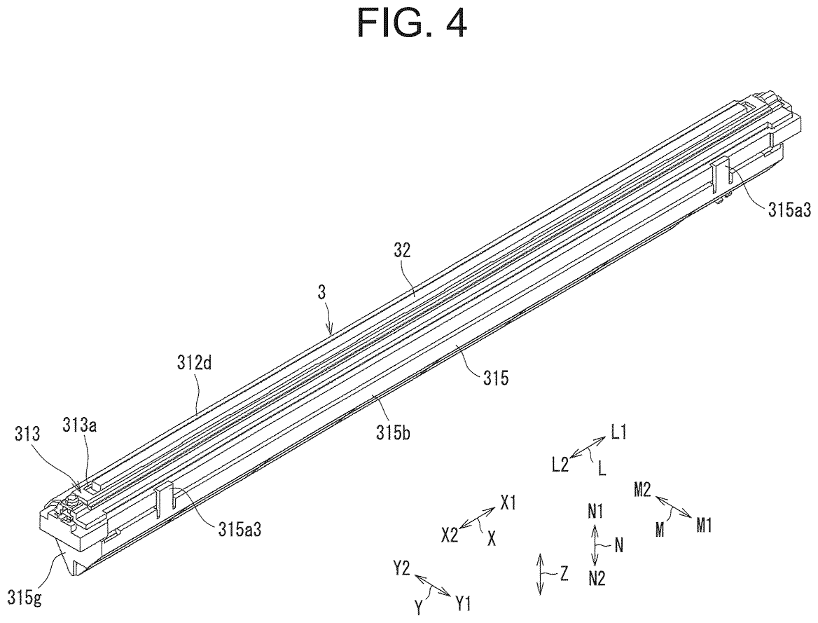

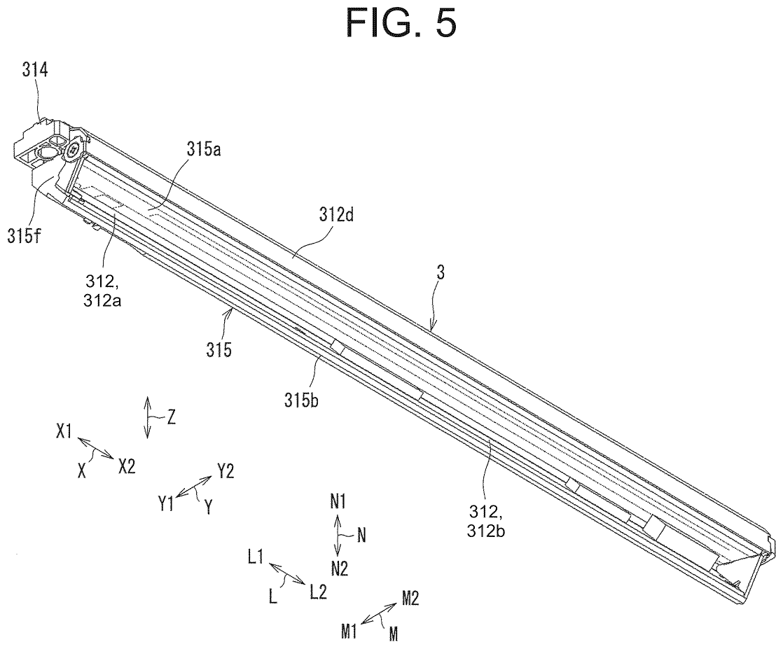

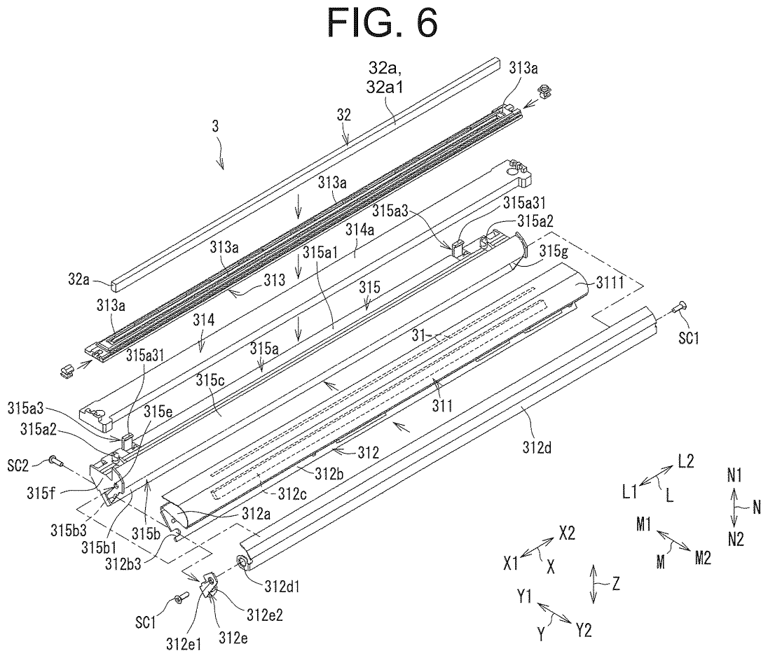

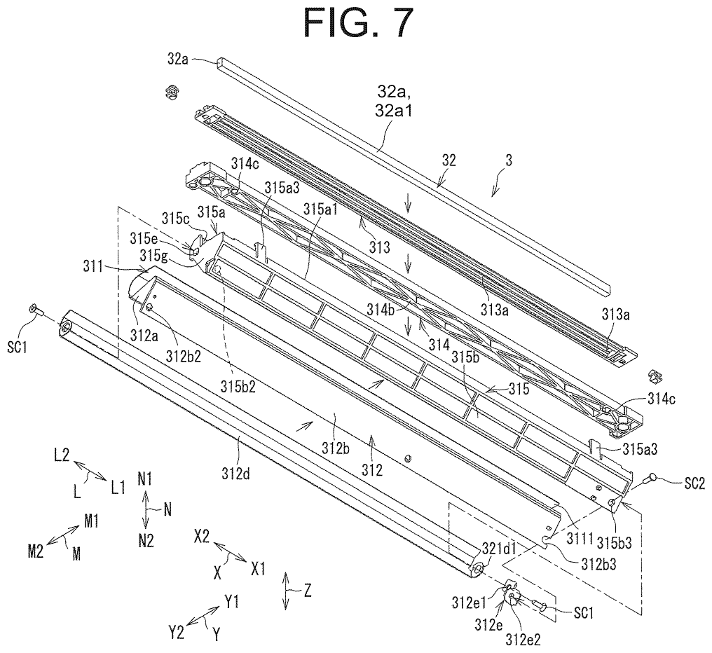

FIG. 2 is a perspective view illustrating that an example of the print heads 3 to 3 in the image forming apparatus 100 according to the present embodiment is mounted on a main body frame FL (FL1 to FL3), as viewed obliquely from above on the front side X1. FIG. 3 is a perspective view of a state in which the print head 3 illustrated in FIG. 2 is supported on a mounting portion 210, as viewed obliquely from above on the front side X1. FIG. 4 is a perspective view of the print head 3 as viewed obliquely from above on the back side X2. FIG. 5 is a perspective view of the print head 3 illustrated in FIG. 4 as viewed obliquely from below on the front side X1. FIGS. 6 and 7 are each an exploded perspective view of the print head 3 illustrated in FIG. 4, as viewed obliquely from above on the front side X1 and obliquely from below on the back side X2.

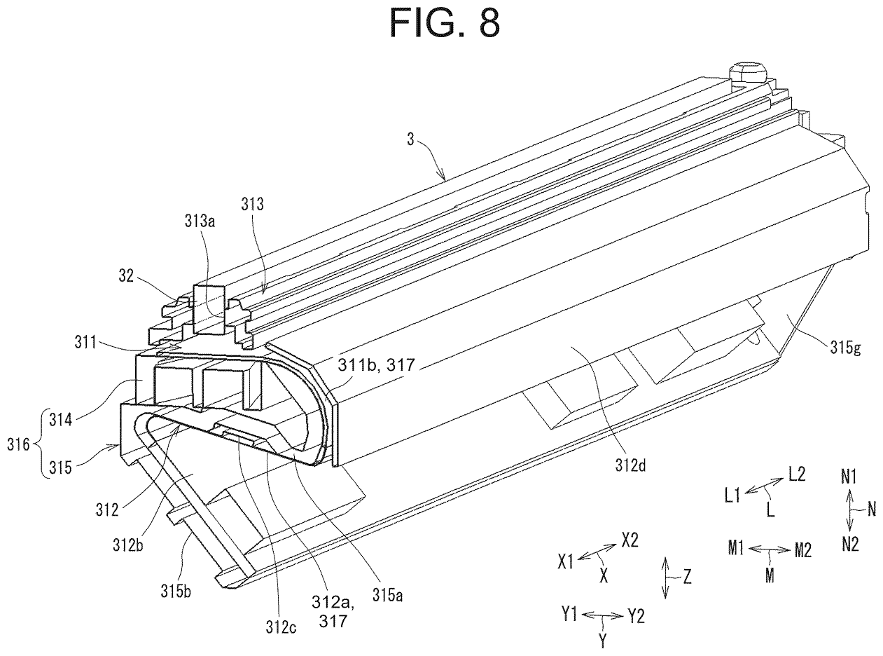

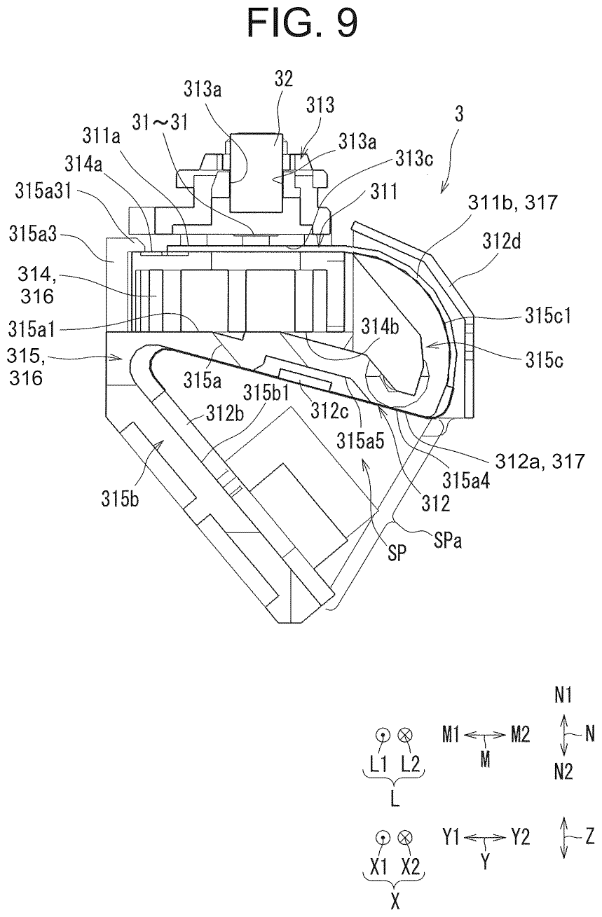

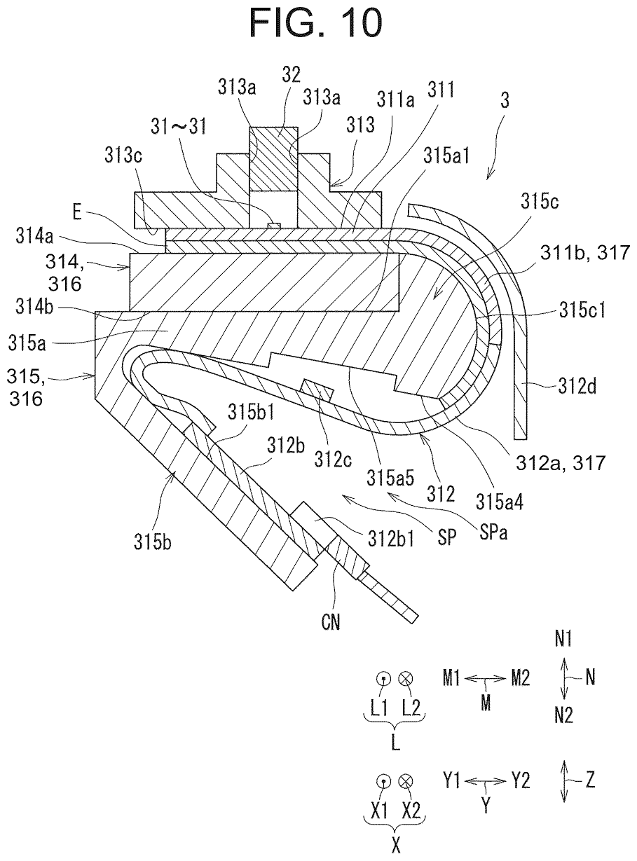

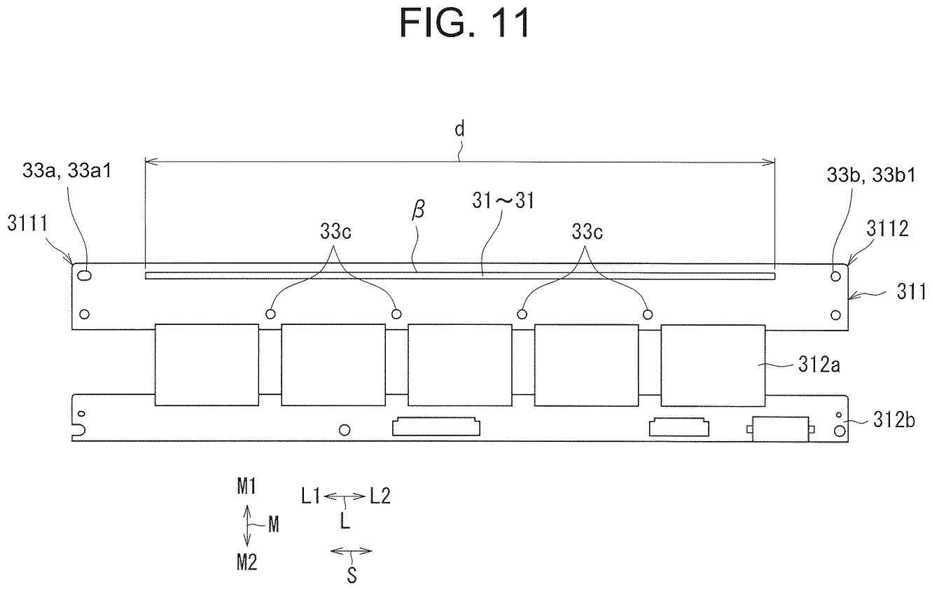

FIG. 8 is a cross-sectional perspective view illustrating the print head 3 as viewed obliquely from above on the front side. FIG. 9 is a cross-sectional view of the print head 3. FIG. 10 is a schematic diagram clearly illustrating the cross-sectional view illustrated in FIG. 9. FIG. 11 is a plan view illustrating a state in which a flexible circuit board 312a extends linearly on a light emitting element panel 311, the flexible circuit board 312a, and a printed wiring board 312b constituting the print head 3.

In the following description, description is made based on a premise that a plurality of light emitting elements 31 to 31 in the print heads 3 to 3 are each an organic EL diode (an organic light-emitting diode: OLED, hereinafter simply referred to as OLED). Note that, the light emitting elements 31 to 31 are not limited to OLED, but may be an inorganic light-emitting diode (LED), a light emitting element such as a nano light-emitting diode (nano-scale light-emitting diode), which is a light-emitting diode (LED) of a size smaller than a micromillimeter, or the like.

Note that, since the print heads 3 to 3, and the like each has the same configuration, in FIGS. 3 to 11, the components are illustrated by one drawing, and in the following description, the print heads 3 to 3, and the like are simply referred to as the print head 3 and the like.

The image forming apparatus 100 according to the present embodiment includes the photosensitive drum 1, and the long print head 3. The print head 3 includes the light emitting element panel 311, and a lens array 32. The light emitting element panel 311 includes the plurality of light emitting elements 31 to 31 (see FIGS. 9 to 11). The light emitting elements 31 to 31 emit light for exposing the surface 1a of the photosensitive drum 1. The light emitting elements 31 to 31 are arranged in a longitudinal direction L of the print head 3, and arrayed in a line. In this example, the light emitting element panel 311 is a film-like panel (flexible OLED panel) (light emitting element panel) in which OLED elements (31 to 31) are mounted. This enables to downsize the print head 3, and achieve the low cost.

The lens array 32 extends in the longitudinal direction L, and collects light emitted from the light emitting elements 31 to 31 onto the surface 1a of the photosensitive drum 1. The lens array 32 is disposed to face the light emitting elements 31 to 31.

The print head 3 is mounted on the mounting portion 210. The mounting portion 210 is provided between the main body frames FL of the image forming apparatus main body 101 (see FIG. 1) (in this example, between the main body frame FL1 on the front side X1, and the main body frame FL2 on the back side X2).

In this example, the print head 3 is mounted between the main body frames FL1 and FL2, on the main body frame FL3 along the rotation axis direction X and the left-right direction Y. The mounting portion 210 is disposed on the main body frame FL3.

### Print Head

As illustrated in FIGS. 8 to 11, the print head 3 further includes a driving member 312, a lens holding member 313, a fixing member 314 (base member), and a main body member 315. A support member 316 is constituted of the fixing member 314 and the main body member 315. The driving member 312 drives the light emitting elements 31 to 31. The lens holding member 313 holds the lens array 32. The fixing member 314 fixes the lens holding member 313 in a state that the light emitting element panel 311 is fixed. The main body member 315 holds the driving member 312, the lens holding member 313, and the fixing member 314.

In this example, the driving member 312 includes the flexible circuit board 312a (connection cable member), the printed wiring board 312b (PWB) (connection substrate), a driving circuit element 312c, and a protection member 312d. One end portion of the connection cable member (312a) is connected to one end portion of the light emitting element panel 311, and the other end portion thereof is connected to one end portion of the printed wiring board 312b. The connection cable member (312a) serves as a flexible circuit board (chip on film: COF) in which the driving circuit element 312c (driver IC) that drives the OLED elements (31 to 31) on the light emitting element panel 311 is mounted on a film. The printed wiring board 312b connected to the connection cable member (312a) includes an input terminal 312b1 (connector terminal) (see FIG. 10), and is connected to a connector CN (see FIG. 10) via the input terminal 312b1. The protection member 312d protects an exposed portion of the light emitting element panel 311 and the connection cable member (312a). The connector CN is connected to an image processing device (not illustrated) provided in the image forming apparatus main body 101. Note that, FIG. 10 illustrates that the light emitting elements 31 to 31 are provided to protrude on an outer surface of the light emitting element panel 311, but this is to clearly illustrate the light emitting elements 31 to 31. Actually, as illustrated in FIG. 9, the light emitting elements 31 to 31 are provided inside in such a way as not to protrude from an outer surface of the light emitting element panel 311 (for example, formed by vapor deposition).

The lens holding member 313 serves as a frame-shaped member that surrounds outer peripheral surfaces 32a to 32a (see FIGS. 6 and 7) of the lens array 32 along an optical axis direction N of the light emitting elements 31 to 31. Herein, the optical axis direction N is a direction (thickness direction) orthogonal to both the longitudinal direction L and a width direction M of the print head 3. The width direction M is a direction orthogonal to an array direction S along a linear direction of the plurality of light emitting elements 31 to 31. The lens array 32 is inserted into an inner side surface 313a of the lens holding member 313 serving as a frame-shaped member. The lens array 32 is configured in such a way that at least a part of the outer peripheral surfaces 32a to 32a (in this example, side surfaces 32a1 and 32a1 along the longitudinal direction L) are held on the lens holding member 313, and are adhesively mounted to at least some positions (in this example, a plurality of positions) by an adhesive (for example, a UV curing adhesive). Further, a periphery of a bonding portion between the lens array 32 and the lens holding member 313 is sealed by a caulking agent (caulking resin). This enables to effectively prevent intrusion of foreign matter such as dust from the bonding portion between the lens array 32 and the lens holding member 313 into the lens holding member 313.

The fixing member 314 is formed into a rectangular shape. A back surface of the light emitting element panel 311 on which the light emitting elements 31 to 31 are provided, which is a side opposite to the light emitting elements 31 to 31, is adhesively mounted to a surface 314a of the fixing member 314 on the side (one side N1) of the photosensitive drum 1 in the optical axis direction N by an adhesive member E (for example, a double-sided adhesive tape) (see FIG. 10). A back surface 313c of the lens holding member 313 is fixed to a panel surface 311a of the light emitting element panel 311 on the side opposite to the fixing member 314. A periphery of a bonding portion between the lens holding member 313 and the light emitting element panel 311 is sealed by a caulking agent (caulking resin). This enables to effectively prevent intrusion of foreign matter such as dust from the bonding portion between the lens holding member 313 and the light emitting element panel 311 into the lens holding member 313.

Note that, relative positions (positions in the longitudinal direction L, in the width direction M, and in the optical axis direction N) of the plurality of light emitting elements 31 to 31, and the lens array 32 are positioned and adjusted in advance in a production process by using a jig or the like.

The main body member 315 includes a placement portion 315a, a bent portion 315b, and a panel guide portion 315c. The placement portion 315a, the bent portion 315b, and the panel guide portion 315c are integrally formed.

The placement portion 315a places the fixing member 314. The placement portion 315a is provided with a placement surface 315al that places the fixing member 314 in such a way as to make contact with a back surface 314b of the fixing member 314 on the side of the mounting portion 210. This enables to securely place the fixing member 314 on the placement surface 315a1 of the placement portion 315a. The placement surface 315a1 of the placement portion 315a is provided with a plurality of (two) positioning protruding portions or recessed portions (in this example, positioning protruding portions 315a2 and 315a2) (see FIG. 6). The back surface 314b of the fixing member 314 is provided with positioning recessed portions or protruding portions (in this example, positioning recessed portions 314c and 314c) associated with the plurality of (two) positioning protruding portions or recessed portions (315a2 and 315a2). This enables to securely position the fixing member 314 with respect to the main body member 315. Further, the placement portion 315a is provided with a plurality of (two) holding portions 315a3 and 315a3 (see FIGS. 6, 7, and 9). The placement portion 315a and the holding portions 315a3 and 315a3 are integrally formed. The holding portions 315a3 and 315a3 detachably hold the fixing member 314 on the placement portion 315a. The holding portions 315a3 and 315a3 restrain the fixing member 314 from moving toward the light emitting elements 31 to 31 (toward the one side N1) in the optical axis direction N. The holding portions 315a and 315a3 include a locking portion 315a31 (see FIG. 9) that locks the surface 314a of the fixing member 314.

The bent portion 315b is bent at an acute angle (for example, 60 degrees or less, in this example, about 50 degrees) with respect to the placement portion 315a. The printed wiring board 312b is fixed to a surface 315b1 (inner side surface) of the bent portion 315b facing the placement portion 315a. The input terminal 312b1 is provided at an end portion on an entrance side (side of an opening portion SPa) of a space SP between the placement portion 315a and the bent portion 315b of the printed wiring board 312b, and the connector CN is connected toward the space SP.

The panel guide portion 315c includes a curved portion 315c1 that folds back a film-like protruding portion 317 toward the space SP from the support member 316 (314 and 315). The curved portion 315c1 is curved in such a way that a portion of the protruding portion 317 on the side of the lens holding member 313 [in this example, between the light emitting element panel 311 and the connection cable member (312a)] is folded back at 180 degrees or more. The curved portion 315c1 protrudes to any one side (in this example, to the other side M2) in the width direction M with respect to the lens holding member 313. A panel portion 311b of the light emitting element panel 311 on the side of the connection cable member (312a), and a portion of the connection cable member (312a) on the side of the light emitting element panel 311 are adhesively mounted to each other by the adhesive member E on the curved portion 315c1. This allows the curved portion 315c1 to securely fold back the protruding portion 317 [in this example, the connection cable member (312a)] within the space SP. The protection member 312d faces a portion of the protruding portion 317 associated with the curved portion 315c1, and is curved along the curved portion 315c1. As illustrated in FIGS. 6 and 7, the protection member 312d is fastened to a fastened portion 315e (female screw) of the main body member 315, after a fastening member SC1 (male screw) passes through a through-hole 312e1 of a holder 312e and through a through-hole 312d1 of the protection member 312d on the one side L1 in the longitudinal direction L. This enables to fix an end portion of the protection member 312d on the one side L1 in the longitudinal direction L to the main body member 315.

Further, the protection member 312d is fastened to the fastened portion 315e of the main body member 315, after the fastening member SC1 passes through a through-hole 312d1 of the protection member 312d on the other side L2 in the longitudinal direction L. This enables to fix an end portion of the protection member 312d on the other side L2 in the longitudinal direction L to the main body member 315. Further, the printed wiring board 312b is configured in such a way that a positioning hole 312b2 of the printed wiring board 312b is positioned at a positioning protruding portion 315b2 of the bent portion 315b on the other side L1 in the longitudinal direction L. In this state, the printed wiring board 312b is fastened to a fastened portion 312e2 (female screw) of the holder 312e, after a fastening member SC2 (male screw) passes through a through-hole 315b3 of the bent portion 315b and through a passing recessed portion 312b3 of the printed wiring board 312b on the one side L1 in the longitudinal direction L. This enables to hold the protection member 312d in a positioned state with respect to the bent portion 315b.

An end portion of one portion [connection cable member (312a)] of the protruding portion 317 mounted inside the space SP on the side of the printed wiring board 312b is folded back at a corner portion between the placement portion 315a and the bent portion 315b, and connected to the printed wiring board 312b.

The driving circuit element 312c is provided in the connection cable member (312a) on the side of the placement portion 315a. A recessed portion 315a5 that prevents interference with the driving circuit element 312c in the connection cable member (312a) is formed in a surface 315a4 (inner side surface) of the placement portion 315a facing the bent portion 315b.

Further, the main body member 315 includes a pair of side plate portions 315f and 315g (see FIGS. 6 and 7) that close both ends of the space SP in the longitudinal direction L.

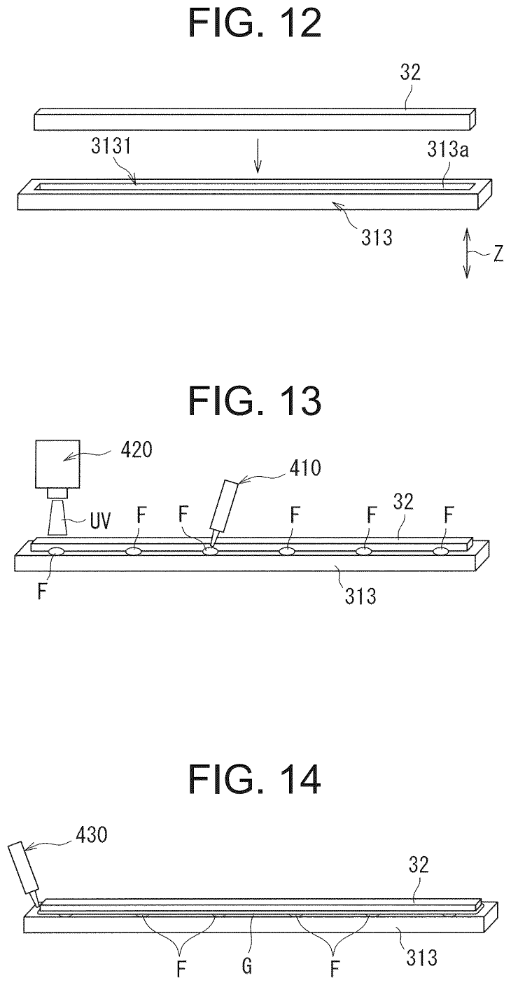

Next, in the following, a manufacturing method of the print head 3 is described with reference to FIGS. 12 to 17.

FIGS. 12 to 17 are each a perspective view for explaining an example of a first step to a sixth step of a manufacturing process of the print head 3. Note that, FIG. 12 to FIG. 17 illustrate steps in which the lens array 32 is provided on the lens holding member 313, the light emitting element panel 311 is provided on the fixing member 314, and the lens holding member 313 is provided on the light emitting element panel 311.

In a manufacturing method of the print head 3, first, as illustrated in FIG. 12, the lens array 32 is inserted into the inner side surface (313a) of the lens holding member 313 (in this example, into a passing oblong hole 3131 along the up-down direction Z) (first step).

Next, as illustrated in FIG. 13, after a UV curing adhesive F is uniformly applied to a plurality of positions on a peripheral area between the lens array 32 and the lens holding member 313 by using a dispenser 410, the UV curing agent F is cured by irradiating an ultraviolet ray UV to the UV curing adhesive F by using a UV irradiation device 420 (second step). This enables to securely hold the lens array 32 on the lens holding member 313.

Next, as illustrated in FIG. 14, a caulking agent G (caulking resin) is applied to the peripheral area between the lens array 32 and the lens holding member 313 by using a caulking agent application device 430, and seals a gap between the lens array 32 and the lens holding member 313 (third step). This enables to prevent intrusion of foreign matter such as dust through the gap between the lens array 32 and the lens holding member 313.

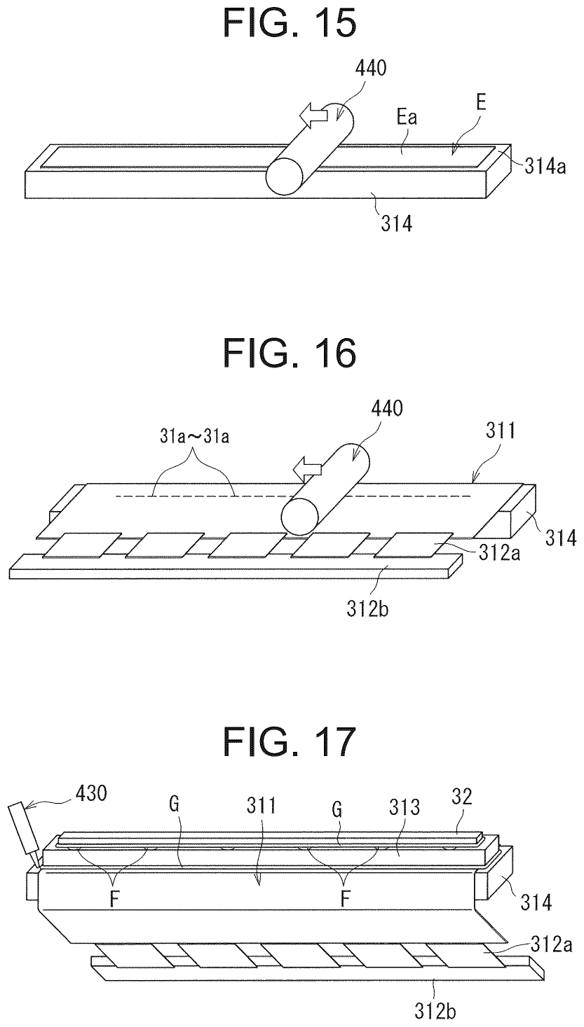

Next, as illustrated in FIG. 15, a double-sided adhesive tape (E) (double-sided adhesive sheet) is attached to the surface (314a) of the fixing member 314 to which the light emitting element panel 311 is to be attached in a state where a protective seal Ea on one surface of the double-sided adhesive tape (E) is attached by using a roller pressure bonding device 440 (fourth step).

Next, as illustrated in FIG. 16, the protective seal Ea on the one surface of the double-sided adhesive tape (E) is peeled off, and the light emitting element panel 311 is attached to the fixing member 314 by using the roller pressure bonding device 440 in a state that the plurality of light emitting elements 31 to 31 on the light emitting element panel 311 are positioned at a reference positioning position on the fixing member 314 (fifth step).

Next, as illustrated in FIG. 17, the lens holding member 313 that holds the lens array 32, which is fabricated in the third step (see FIG. 14), is placed on the light emitting element panel 311 attached to the fixing member 314, the caulking agent G (caulking resin) is applied to a peripheral area between the lens holding member 313 and the light emitting element panel 311 by using the caulking agent application device 430, and a gap between the lens holding member 313 and the light emitting element panel 311 is sealed (sixth step). This enables to prevent intrusion of foreign matter such as dust through the gap between the lens holding member 313 and the light emitting element panel 311.

### Present Embodiment

As illustrated in FIG. 11, the light emitting element panel 311 according to the present embodiment is formed into a film-like shape, and includes the plurality of light emitting elements 31 to 31. The plurality of light emitting elements 31 to 31 are arrayed in a line.

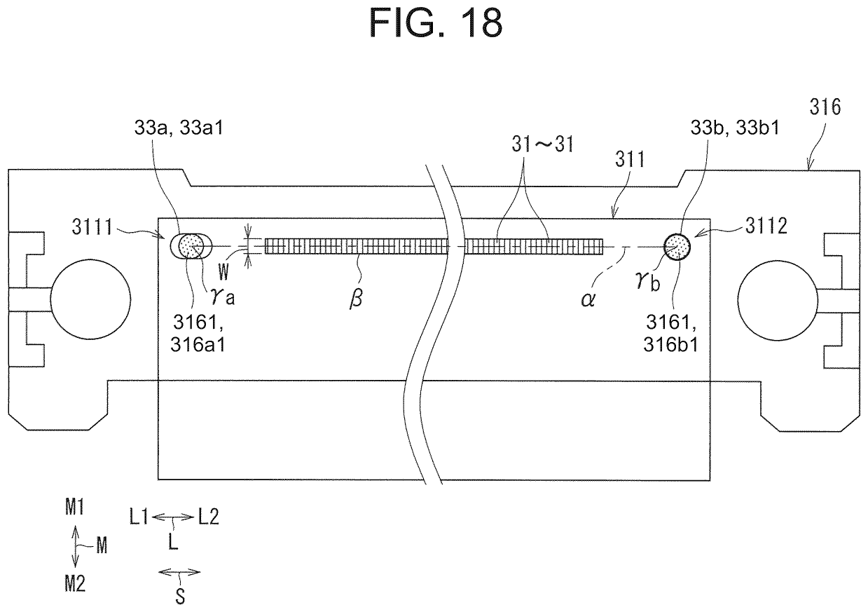

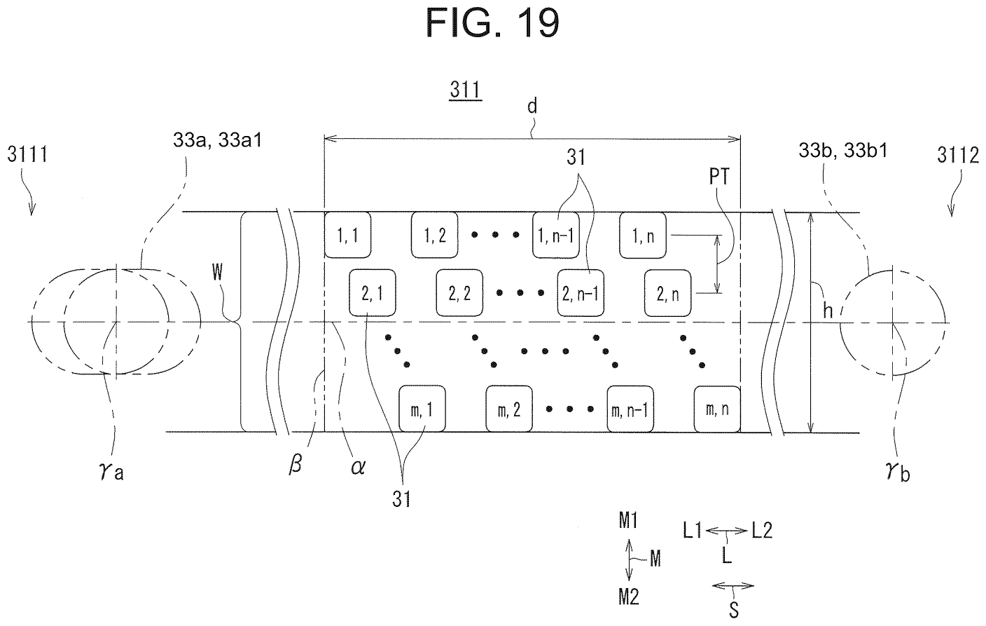

FIG. 16 is a plan view illustrating an example of some of the plurality of light emitting elements 31 to 31 on the light emitting element panel 311, and the pair of positioning portions 33a and 33b (33a1 and 33b1). FIG. 19 is an enlarged view enlarging the example of some of the plurality of light emitting elements 31 to 31 on the light emitting element panel 311, and the pair of positioning portions 33a and 33b (33a1 and 33b1) illustrated in FIG. 18.

As illustrated in FIGS. 18 and 19, the positioning portions 33a and 33b for positioning the plurality of light emitting elements 31 to 311 at a reference position positioning position on a positioning target object (in this example, the support member 316) are provided both end portions 3111 and 3112 of the light emitting element panel 311 in the array direction S (longitudinal direction L).

A virtual straight line α connecting centers γa and γb of the pair of positioning portions 33a and 33b respectively provided on the both end portions 3111 and 3112 lies within the width W of the plurality of light emitting elements 31 to 31 in the width direction M. Herein, the width W of the plurality of light emitting elements 31 to 31 means a range in the width direction M of a rectangular placement area β surrounding the entire outer periphery of the plurality of light emitting elements 31 to 31. Specifically, as illustrated in FIG. 19, the plurality of light emitting elements 31 to 31 are arrayed in m rows and n columns in the array direction S and in the width direction M. The plurality of light emitting elements 31 to 31 are shifted to any one side (in this example, to the other side L2 in the longitudinal direction L) in the array direction S in such a way that the light emitting elements 31 and 31 adjacent to each other in the width direction M partially overlap each other in the array direction S. In this example, a pitch PT (see FIG. 19) in the width direction M between the adjacent light emitting elements 31 to 31 is 68.80 μm, and the width W of the placement area β in the width direction M is 241.4 μm.

### First Embodiment

In a film-like light emitting element panel 311, positioning portions 33a and 33b serve as a positioning reference for a plurality of light emitting elements 31 and 31. Therefore, as the positioning portions 33a and 33b are closer to the plurality of light emitting elements 31 and 31, a positioning error of the plurality of light emitting elements 31 and 31 with respect to a reference positioning position on a positioning target object (316) can be reduced.

In this regard, according to the present embodiment, since a virtual straight line α lies within a width W of the plurality of light emitting elements 31 to 31 in a width direction M, it is possible to improve positioning accuracy of the plurality of light emitting elements 31 to 31 with respect to a reference positioning position on the positioning target object (316). This enables to accurately position the plurality of light emitting elements 31 to 31 at the reference positioning position on the positioning target object (316). Therefore, an adjustment time of a subsequent adjustment process can be shortened, and adjustment work can be improved.

Herein, regarding the point that “the virtual straight line α lies within the width W of the plurality of light emitting elements 31 to 31”, preferably, the virtual straight line α may be located at a middle in the width direction M of the width W of the plurality of light emitting elements 31 to 31 in the width direction M. However, as long as the virtual straight line α lies within the width W of the plurality of light emitting elements 31 to 31, the virtual straight line α may be oblique with respect to an array direction S. That is, as long as the virtual straight line α lies within the width W of the plurality of light emitting elements 31 to 31, positioning accuracy lies within an allowable range, even in a case where the virtual straight line α becomes oblique with respect to the array direction S. For example, when it is assumed that the size d (see FIGS. 11 and 19) of the entirety (placement area β) of the plurality of light emitting elements 31 to 31 in the array direction S is about 300 mm, and the size of the entirety (placement area β) of the plurality of light emitting elements 31 to 31 in the width direction M is about 0.24 mm, even in a case where the virtual straight line α becomes oblique within the width W of the plurality of light emitting elements 31 to 31, the inclination angle of the virtual straight line α with respect to the array direction S is about 0.046 degree at the maximum, which is an allowable level of positioning accuracy.

In this configuration, there is room for positioning accuracy of the positioning portions 33a and 33b with respect to the light emitting element panel 311.

### Second Embodiment

In the present embodiment, a plurality of light emitting elements 31 to 31, and a pair of positioning portions 33a and 33b are provided on any one side (in this example, on one side M1) in a width direction M of a light emitting element panel 311.

In this configuration, the light emitting element panel 311 can be placed evenly on a positioning target object (316) without being placed unevenly in the width direction M.

### Third Embodiment

Preferably, a middle in a width direction M of a width W of a plurality of light emitting elements 31 to 31 may be aligned with centers γa and γb of a pair of positioning portions 33a and 33b.

In this regard, in the present embodiment, the pair of positioning portions 33a and 33b are formed of a shape including a point symmetrical shape.

In this configuration, the centers γa and γb of the pair of positioning portions 33a and 33b can be easily determined by a shape including a point symmetrical shape. This makes it easy to align the middle in the width direction M of the width W of the plurality of light emitting elements 31 to 31 with the centers γa and γb of the pair of positioning portions 33a and 33b. As a point symmetrical shape, representatively, a circular shape (a through-hole, and in a case where the positioning portions 33a and 33b are a positioning mark, a circle mark) can be exemplified.

### Fourth Embodiment

A print head 3 according to the present embodiment includes a light emitting element panel 311, and a support member 316 (in this example, a fixing member 314 and a main body member 315) that supports the light emitting element panel 311. A positioning target object is the support member 316.

In this configuration, in a case where the light emitting element panel 311 is supported by the support member 316 (see FIGS. 9, 10, and 18), a plurality of light emitting elements 31 to 31 can be accurately positioned at a reference positioning position on the support member 316.

### Fifth Embodiment

In the present embodiment, a support member 316 (in this example, a main body member 315) includes a curved portion 315c1 (curved surface) (see FIGS. 9 and 10) that is curved in a convex shape in a width direction M. A light emitting element panel 311 includes a curved panel portion (311b) (see FIGS. 9 and 10) disposed along the curved portion 315c1 of the support member 316. In this case, a curved position of the light emitting element panel 311 on the curved portion 315c1 of the support member 316 is difficult to recognize, which may deteriorate workability of mounting work of the light emitting element panel 311 to the support member 316.

In this regard, in the present embodiment, the curved panel portion (311b) is formed with indicators 33c to 33c (see FIG. 11) (in this example, through-holes) indicating a folding position of a curve of the curved portion 315c1 in the width direction M.

In this configuration, a curved position of the light emitting element panel 311 on the curved portion 315c1 of the support member 316 can be easily recognized, which enables to improve workability of mounting work of the light emitting element panel 311 to the support member 316.

### Sixth Embodiment

In the present embodiment, at least one (in this example, both) of a pair of positioning portions 33a and 33b is through-holes 33a1 and 33b1 (see FIGS. 18 and 19). A support member 316 is provided with a reference positioning portion 3161 (for example, a reference protruding portion, a reference mark, in this example, a reference protruding portion) (see FIGS. 18 and 19) that is aligned with the through-holes 33a1 and 33b1.

In this configuration, the reference positioning portion 3161 (in this example, reference protruding portions 316a1 and 316b1) provided on the support member 316 is aligned with (in this example, inserted into) the through-holes 33a1 and 33b1 which are at least one (in this example, both) of the pair of positioning portions 33a and 33b. Therefore, it is possible to more accurately position a plurality of light emitting elements 31 to 31 at a reference positioning position on the positioning target object (316).

### Seventh Embodiment

As illustrated in FIGS. 18 and 19, in a case where a reference positioning portion 3161 is reference protruding portions 316a1, 316b1, and both of a pair of positioning portions 33a and 33b are through-hole 33a1 and 33b1, if a distance between the pair of reference protruding portions 316a1 and 316b1 in an array direction S becomes longer or shorter than a normal distance due to factors such as a variation in components, it becomes difficult to insert the pair of reference protruding portions 316a1 and 316b1 into the pair of through-holes 33a1 and 33b1.

In this regard, in the present embodiment, the through-hole 331a of the positioning portion 33a, which is one of the pair of positioning portions 33a and 33b, is formed into an oblong hole extending in the array direction S, and the through-hole 33b1 of the other positioning portion 33b is formed into a circular hole. The reference positioning portion 3161 is a pair of reference protruding portions 316a1 and 316b1 (see FIGS. 18 and 19), which are respectively inserted into the oblong hole (33a1) and the circular hole (33b1). Specifically, the pair of reference protruding portions 316a1 and 316b1 can be formed into a circular shape or a cross shape (in this example, a circular shape) in a plan view.

In this way, even in a case where the distance between the pair of reference protruding portions 316a1 and 316b1 in the array direction S becomes longer or shorter than the normal distance due to factors such as a variation in accuracy, the pair of reference protruding portions 316a1 and 316b1 can be easily inserted into the pair of through-holes 33a1 and 33b1.

### Eighth Embodiment

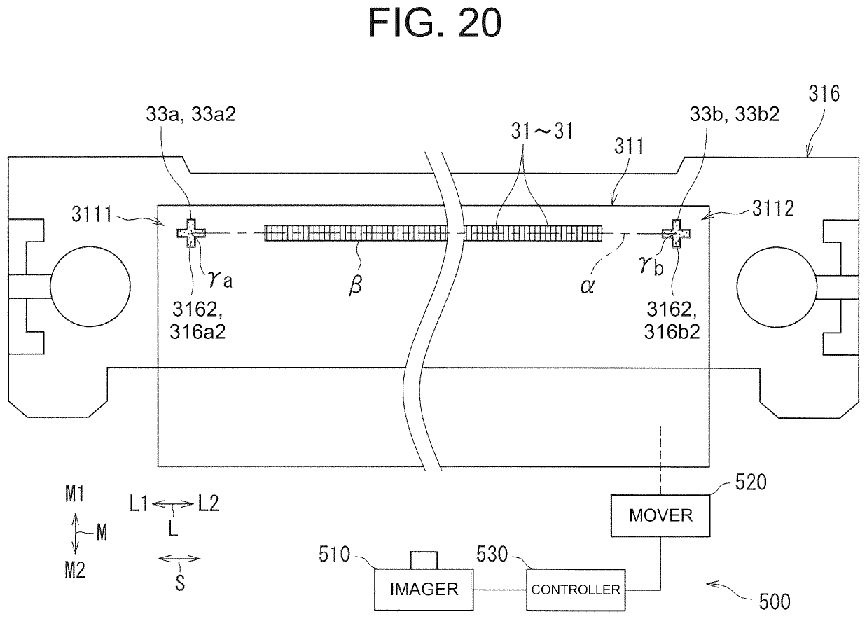

FIG. 20 is a plan view illustrating another example of some of a plurality of light emitting elements 31 to 31 on a light emitting element panel 311, and a pair of positioning portions 33a and 33b (33a2 and 33b2).

In the present embodiment, the light emitting element panel 311 is formed of a light transmissive member (for example, light transmittance of 20% or more, more preferably 30% or more, and still more preferably 50% or more). At least one (in this example, both) of the pair of positioning portions 33a and 33b is positioning marks 33a2 and 33b2. A support member 316 is provided with a reference positioning portion 3162 [for example, a reference recessed portion (engraved mark), or a reference mark (printed)] (see FIG. 20), which is aligned with the positioning marks 33a2 and 33b2. In this example, the positioning marks 33a2 and 33b2, and reference marks 316a2 and 316b2 are printed on the light emitting element panel 311 and the support member 316, respectively.

In this configuration, the reference positioning portion 3162 (in this example, the reference marks 316a2 and 316b2) provided on the support member 316 is aligned with (overlapped on) the positioning marks 33a and 33b, which are at least one (in this example, both) of the pair of positioning portions 33a and 33b. Therefore, it is possible to more accurately position the plurality of light emitting elements 31 to 31 at a reference positioning position on the positioning target object (316).

In a case where the plurality of light emitting elements 31 to 31 are positioned at the reference positioning position on the positioning target object (316), a worker can align the positioning marks 33a2 and 33b2 on the light emitting element panel 311 with respect to the reference positioning portion 3162 on the positioning target object (316). Further, the positioning marks 33a2 and 33b2 may be aligned with respect to the reference positioning portion 3162 by using an adjustment device 500 including an imager 510 (camera), a mover 520 that moves the light emitting element panel 311 relative to the positioning target object (316) in an array direction S and in a width direction M, and a controller 530. In a case where the adjustment device 500 is used, in the adjustment device 500, the controller 530 performs positioning of the positioning marks 33a2 and 33b2 with respect to the reference positioning portion 3162 by image processing based on an image from the imager 510, and controls the mover 520 in such a way that the positioning marks 33a2 and 33b2 are aligned with respect to the reference positioning portion 3162.

### Ninth Embodiment

In the present embodiment, both of a pair of positioning portions 33a and 33b are circular or cross-shaped (in this example, cross-shaped) positioning marks. A reference positioning portion 3161 is a pair of reference marks 316a2 and 316b2 (see FIG. 20) that are overlapped on a pair of positioning marks 33a2 and 33b2. Specifically, the pair of reference marks 316a2 and 316b2 may be circular or cross-shaped marks (in this example, cross-shaped marks), which are aligned by being overlapped on the pair of positioning marks 33a2 and 33b2 having a circular shape or a cross shape (in this example, a cross shape).

In this way, in any of a case where a worker aligns the positioning marks 33a2 and 33b2 with respect to the reference marks 316a2 and 316b2, and a case where the worker aligns the positioning marks 33a2 and 33b2 with respect to the reference marks 316a2 and 316b2 by using the adjustment device 500, the positioning marks can be easily aligned with respect to the reference marks.

### Tenth Embodiment

In the present embodiment, a pair of positioning portions 33a and 33b are formed of a shape including an intersection (in this example, a cross shape).

In this configuration, centers γa and γb of the pair of positioning portions 33a and 33b can be easily determined by a shape including an intersection. This makes it easy to align a middle in a width direction M of a width W of a plurality of light emitting elements 31 to 31 with the centers γa and γb of the pair of positioning portions 33a and 33b. As a shape including an intersection, representatively, a cross shape (a so-called dragonfly mark) can be exemplified.

### Eleventh Embodiment

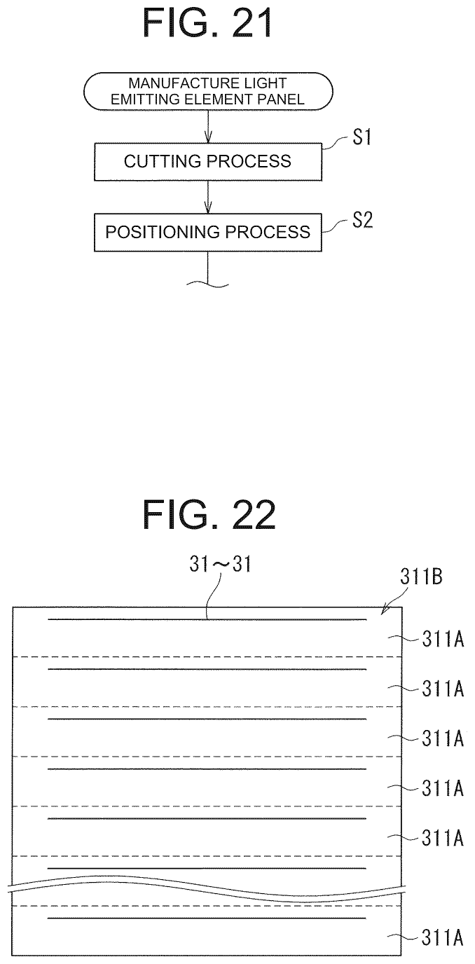

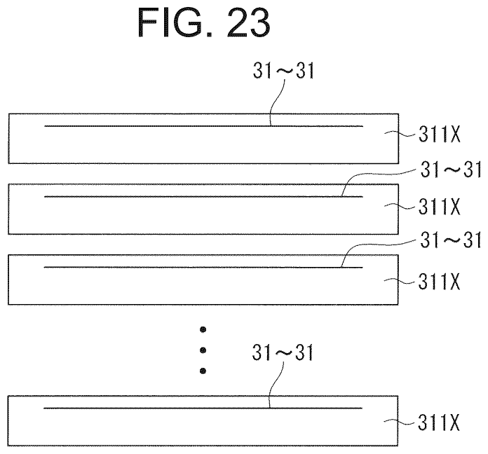

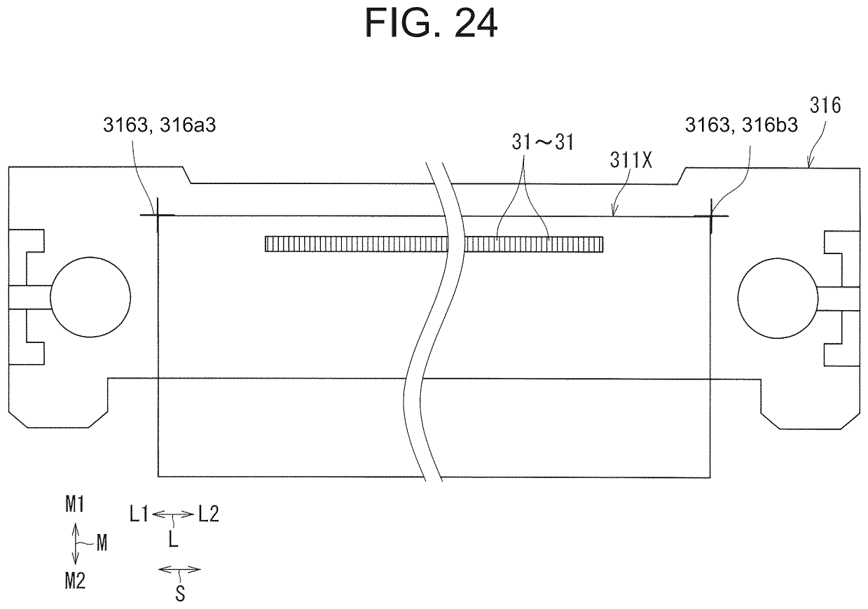

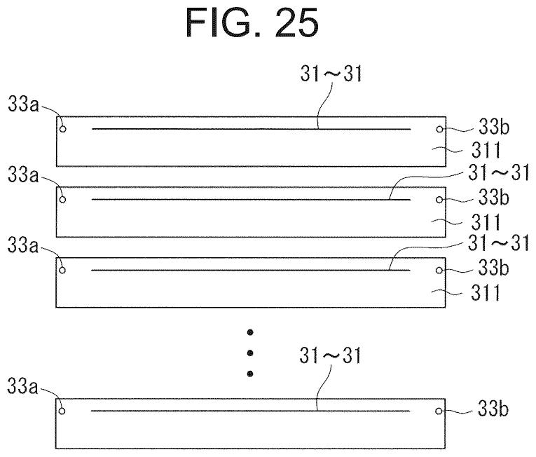

FIG. 21 is a schematic block diagram illustrating a cutting step S1 and a positioning step S2 in a manufacturing process of a light emitting element panel 311 according to the present embodiment. FIG. 22 is a plan view illustrating an example of a connecting panel member 311B. FIG. 23 is a plan view illustrating an example of light emitting element panels 311X to 311X cut in a conventional cutting step. FIG. 24 is a plan view illustrating an example in which the conventional light emitting element panel 311X is positioned with respect to a positioning target object (316) by using a contour line in a width direction M, as a reference position. Further, FIG. 25 is a plan view illustrating an example of light emitting element panels 311 to 311 cut in the cutting step S1 according to the present embodiment.

A conventional manufacturing method of the light emitting element panel 311X generally includes a cutting step of cutting a connecting panel member 311B (see FIG. 22), in which a plurality of unprocessed light emitting element panels 311A to 311A are connected in the width direction M for each of the individual light emitting element panels 311X to 311X (see FIG. 23), and a positioning step of positioning a plurality of light emitting elements 31 to 31 with respect to the positioning target object (316).

However, in the conventional positioning step, in a case where a positioning portion is provided with respect to the individually cut light emitting element panels 311X to 311X, as illustrated in FIG. 24, for example, it is conceived that the contour line of the light emitting element panel 311X in the width direction M is set as a reference position, but the following inconvenience may occur.

That is, positioning accuracy between the panel outer shape and the plurality of light emitting elements 31 to 31 is not good due to a dimensional variation of the panel outer shape of the light emitting element panel 311X in the width direction M, or the like. Therefore, the light emitting element panel 311X is likely to deviate from a reference positioning portion 3163 (reference marks 316a3 and 316b3) on the positioning target object (316). Then, positioning accuracy of the plurality of light emitting elements 31 to 31 with respect to the reference positioning position on the positioning target object (316) deteriorates.

In this regard, in the manufacturing method of the light emitting element panel 311 as described in the first embodiment to the tenth embodiment, in the cutting step S1, as illustrated in FIG. 25, the positioning portions 33a and 33b are formed on the light emitting element panel 311 simultaneously with cutting for each individual light emitting element panel 311. In the positioning step S2, the plurality of light emitting elements 31 to 31 are positioned with respect to the positioning target object (316) by the positioning portions 33a and 33b.

In this way, it is possible to effectively prevent deviation of the light emitting element panel 311 from the reference positioning portions 3161 and 3162 on the positioning target object (316), regardless of positioning accuracy between the panel outer shape and the plurality of light emitting elements 31 to 31 due to a dimensional variation of the panel outer shape of the light emitting element panel 311 in the width direction M, or the like. Therefore, it is possible to improve positioning accuracy of the plurality of light emitting elements 31 to 31 with respect to the reference positioning position on the positioning target object (316).

The present disclosure is not limited to the embodiments described above, and can be implemented in various other forms. Therefore, the above-described embodiments are merely an example in all aspects, and should not be construed in a restrictive way. The scope of the present disclosure is defined by the scope of the claims, and is not constrained by the text of the specification. Further, all modifications and variations that come within the equivalent scope of the claims are within the scope of the present disclosure.

What is claimed is:

1. A light emitting element panel being a film-like light emitting element panel including a plurality of light emitting elements arrayed in a line, comprising:
a positioning portion that positions the plurality of light emitting elements at a reference positioning position on a positioning target object, on both end portions of the light emitting element panel in an array direction along the linear direction of the plurality of light emitting elements, wherein
a virtual straight line connecting centers of a pair of positioning portions respectively provided on the both end portions lies within a width of the plurality of light emitting elements in a width direction orthogonal to the array direction.

2. The light emitting element panel according to claim 1, wherein
the virtual straight line is oblique with respect to the array direction within a width of the plurality of light emitting elements.

3. The light emitting element panel according to claim 1, wherein
the plurality of light emitting elements and the pair of positioning portions are provided on any one side in the width direction of the light emitting element panel.

4. The light emitting element panel according to claim 1, wherein
the pair of positioning portions are formed of a point symmetrical shape or a shape including an intersection.

5. A print head comprising:
the light emitting element panel according to claim 1; and
a support member that supports the light emitting element panel, wherein
the positioning target object is the support member.

6. The print head according to claim 5, wherein
the support member includes a curved portion that is curved in a convex shape in the width direction,
the light emitting element panel includes a curved panel portion that is disposed along the curved portion of the support member, and
the curved panel portion is provided with an indicator that indicates a folding position of a curve of the curved portion in the width direction.

7. The print head according to claim 5, wherein
at least one of the pair of positioning portions is a through-hole, and
the support member is provided with a reference positioning portion that is aligned with the through-hole.

8. The print head according to claim 7, wherein
the through-hole of one of the pair of positioning portions is formed of an oblong hole extending in the array direction, and the through-hole of the other positioning portion is formed of a circular hole, and
the reference positioning portion is a pair of reference protrusions respectively inserted into the oblong hole and the circular hole.

9. The print head according to claim 5, wherein
the light emitting element panel is formed of a light transmissive member,
at least one of the pair of positioning portions is a positioning mark, and
the support member is provided with a reference positioning portion that is aligned with the positioning mark.

10. The print head according to claim 9, wherein
both of the pair of positioning portions are the positioning mark of a circular shape or a cross shape, and
the reference positioning portion is a pair of reference marks that are overlapped on the pair of positioning marks.

11. An image forming apparatus comprising the print head according to claim 5.

12. A light emitting element panel manufacturing method of manufacturing the light emitting element panel according to claim 1, comprising
cutting, into each of the light emitting element panels, a connecting panel member in which a plurality of the light emitting element panels, before being processed, are connected in the width direction, wherein
the cutting includes forming the positioning portion on the light emitting element panel simultaneously with cutting into each of the light emitting element panels.
